(19) United States
(12) Patent Application Publication
(10) Pub. No.: US 2015/0028312 A1
(43) Pub. Date: Jan. 29, 2015

(54) OPTOELECTRONIC COMPONENT, METHOD FOR PRODUCING AN OPTOELECTRONIC COMPONENT, DEVICE FOR SEPARATING A ROOM, AND PIECE OF FURNITURE

(71) Applicant: OSRAM Opto Semiconductors GmbH, Regensburg (DE)

(72) Inventors: Erwin Lang, Regensburg (DE); Thomas Dobbertin, Regensburg (DE)

(21) Appl. No.: 14/370,970

(22) PCT Filed: Jan. 7, 2013
(86) PCT No.: PCT/EP2013/050135

§ 371 Date: Jul. 8, 2014

(30) Foreign Application Priority Data
Jan. 10, 2012 (DE) 10 2012 200 224.3

(51) Int. Cl. H01L 51/52; H01L 51/56

(52) U.S. Cl. CPC H01L 51/5206; H01L 51/56; H01L 51/5234; H01L 51/524; H01L 2251/5323
USPC 257/40; 438/34

(57) ABSTRACT

Various embodiments relate to an optoelectronic component, including a first electrode layer, a first organic functional layer structure on or over the first electrode layer, a nontransparent second electrode layer on or over the first organic functional layer structure, a second organic functional layer structure on or over the second electrode layer, and a third electrode layer on or over the second organic functional layer structure. The material for the second electrode layer is selected in such a way that a matt impression of at least one side of the optoelectronic component is imparted.

### RELATED APPLICATIONS

The present application is a national stage entry according to 35 U.S.C. §371 of PCT application No.: PCT/EP2013/050135 filed on Jan. 7, 2013, which claims priority from German application No.: 10 2012 200 224.3 filed on Jan. 10, 2012, and is incorporated herein by reference in its entirety.

### TECHNICAL FIELD

Various embodiments relate to an optoelectronic component, to a method for producing an optoelectronic component, to a device for separating a room, and to a piece of furniture.

### BACKGROUND

An optoelectronic component is suitable for generating light or for generating electricity. Known optoelectronic components are, for example, light-emitting diodes, in particular organic light-emitting diodes, or solar cells, in particular organic solar cells. Organic light-emitting diodes are being used ever more frequently for new types of lighting solutions, in order to contribute by special lighting of rooms to the creation of a good and pleasant room atmosphere or performance-promoting working atmosphere, for example by mixing direct and indirect lighting.

Organic light-emitting diodes (OLEDs) are in most embodiments mirrored on one side and therefore emit light only in one direction (for example on the substrate side in the case of bottom emitters or on the cover glass side in the case of top emitters). For applications in which the emission on both sides is intended to be achieved, two OLEDs are arranged in such a way that the light emission takes place in both emission directions. This has the disadvantage that two times the number of OLEDs has to be used, which leads to a considerable cost increase. Further disadvantages are due to the significantly thicker installation height of such lamps, so that the advantages of the very thin and esthetically agreeable OLEDs are mostly lost. This gives rise to great restrictions in the design freedom.

For emission of light on both sides, transparent OLEDs are furthermore also known, in which the organic functional layer structure of the OLED, including electrode layers, is configured so as to be transparent or semitransparent, so that light emission is possible on the substrate side and on the cover glass side. Transparent OLEDs have the further advantage that they are transparent when switched off, which when switched off allows on the one hand viewing through the transparent OLED, or the incidence of external light through the transparent OLED. The transparent OLEDs in principle emit on both sides. A great disadvantage of these components is that only about 20% of the light generated can be emitted into the two half-planes, and the rest of the light is wave-guided away and is eliminated by internal losses (for example by total internal reflection and internal absorption).

Various embodiments make it possible to produce highly efficient OLED components, efficient light emission on both sides (the substrate side and the cover glass side) being possible, and therefore to produce highly efficient lamps which permit emission of light to both sides of the lamp and which thus combine a mixture of direct and indirect light components in one lamp. This offers great design freedoms and new possibilities for lamp concepts, which, for example in the lighting of rooms, can contribute to a good and pleasant room atmosphere or performance-promoting working atmosphere.

### SUMMARY

In various embodiments, an optoelectronic component is provided. The optoelectronic component may include a first electrode layer, a first organic functional layer structure on or over the first electrode layer, a nontransparent second electrode layer on or over the first organic functional layer structure, a second organic functional layer structure on or over the second electrode layer, and a third electrode layer on or over the second organic functional layer structure.

The organic functional layer structures respectively include, for example, a transport layer and an emitter layer. When a voltage is applied to the first and second electrode layers, the first organic functional layer structure emits light, and when a voltage is applied to the second and third electrode layers, the second organic functional layer structure emits light. The optoelectronic component allows efficient light emission in two mutually opposite directions. The optoelectronic component may act reflectively or nonreflectively from both directions, or it may act reflectively only from one of the two directions. The two organic functional layer structures may have different emission characteristics, for example one of the layer structures may have a warm, for example warm-white, emission characteristic and the other of the layer structures may have a cold, for example cold-white, emission characteristic. The light emission of the layer structures may be directed mutually independently, for example along the surface normals, or it may have a Lambertian emission profile or be butterfly-shaped. Furthermore, one of the layer structures may emit light of a different color than the other layer structure, so that the optoelectronic component emits light of a different color in a first emission direction than in a second emission direction. Furthermore, the first electrode layer, the first organic functional layer structure and the second electrode layer may form a bottom emitter, and/or the second electrode layer, the second organic functional layer structure and the third electrode layer may form a top emitter. The second electrode layer is formed so as to be nontransparent, which in this context may mean that the second electrode layer is not transparent for the light from the first and/or second functional layer structure. For example, the second electrode layer may be formed so as to be reflective on one or both of its sides. This may contribute to light in one of the emission directions having a different color, a different emission characteristic and/or a different color temperature than the light in the other emission direction. For example, by selecting particular materials for the individual electrode layers, an impression which is matt on both sides, matt on one side and reflective on one side, or reflective on both sides, may be imparted. Furthermore, a viewing angle dependency on the two sides may be set to be the same or different.

The organic functional layer structure may be composed of organic layers which emit light of different colors, so that the corresponding layer structure emits light that is composed of the light of the individual organic layers.

The emission ratio in the two directions can thereby be controlled. The emission color may be set mutually independently in the two directions (for example neutral white, cold white, or subranges of the visual spectrum, such as red, green, blue, etc.). The emission characteristic may be set mutually independently on the two sides and in the emission directions.

It is possible to produce lamps in which, for example, one side is reflective and which therefore generate a very high-quality and esthetically appealing impression for certain applications. In the other emission direction, a high efficiency of the OLED or of the lamp may be achieved by means of output structures (for example ceiling lamp with a reflective surface at the bottom for the optical appearance and the direct light component, and matt appearance upward for the indirect lighting component).

According to various embodiments, the optoelectronic component furthermore includes a substrate, the first electrode layer being arranged on or over the substrate. The substrate may include glass or a sheet, and may be provided with one or more barrier layers. The emission of the light in one of the two directions then takes place on the substrate side.

According to various embodiments, the optoelectronic component furthermore includes a cover layer on or over the third electrode layer. The cover layer may include glass, a sheet and/or a coating, and may be provided with one or more barrier layers.

According to various embodiments, the optoelectronic component furthermore includes at least one encapsulation layer, over which the first electrode layer is arranged, and/or which is arranged over the third electrode layer. The encapsulation layer may include a first encapsulation layer, which encapsulates the first electrode layer and the first functional layer structure, and/or a second encapsulation layer, which encapsulates the second electrode layer and the second functional layer structure. The encapsulation layers protect the corresponding functional layer structures from moisture and dirt.

According to various embodiments, the optoelectronic component furthermore includes at least one additional layer, over which the substrate is arranged, which is arranged between the substrate and the first electrode layer, which is arranged between the first electrode layer and the first organic functional layer structure, which is arranged between the first organic functional layer structure and the second electrode layer, which is arranged between the second electrode layer and the second organic functional layer structure, which is arranged between the second organic functional layer structure and the third electrode layer, which is arranged between the third electrode layer and the cover layer, and/or which is arranged over the cover layer. In other words, the additional layer may be arranged on, under, in or between each other of the aforementioned layers, such as the electrode layers, the encapsulation layers and/or the organic functional layer structures, and the substrate or the cover glass. A plurality of additional layers may furthermore be arranged at said positions.

The additional layer under the substrate or the additional layer on the cover layer may be formed as external output structures. The other additional layers may be formed as internal output structures. With the aid of the additional layers, for example, the transmissivity or the reflectivity of the electrode layers, or alternatively the emission ratio in the two emission directions, can be set. Furthermore, an output efficiency of the light generated can be improved. Furthermore, emission of light with different colors may be set in the two emission directions, for example by at least one of the additional layers being formed as a color filter. Furthermore, the color temperature of the light emitted may be set with the aid of the additional layers, for example by using an electrochromic or thermochromic layer as an additional layer. The additional layer may also include one, two or more sublayers. The additional layer, or optionally its sublayers, may include one or more output layers, one or more output structures, one or more planarization layers, and/or refractive or diffractive elements in a matrix. Such an output structure may be a processed sublayer of the substrate, of the electrode layers, of the organic functional layer structures, or of the cover layer. For example, the output structure may be texturing of the substrate, of the electrode layers, of the organic functional layer structures, of the encapsulation layers, or of the cover layer.

In various embodiments, a method for producing the optoelectronic component is provided, the method including the steps of: formation of the first electrode layer, formation of the first organic functional layer structure on or over the first electrode layer, formation of the second electrode layer on or over the first organic functional layer structure, formation of the second organic functional layer structure on or over the second electrode layer, and formation of the third electrode layer on or over the second organic functional layer structure.

According to various embodiments, the substrate is provided, and the first electrode layer is formed on or over the substrate. The substrate may include glass or a sheet, and/or it may be provided with one or more barrier layers.

According to various embodiments, the cover layer is formed on or over the third electrode layer. The cover layer may include glass, a sheet or a coating.

According to various embodiments, at least the encapsulation layer is formed under the first electrode layer and/or over the third electrode layer.

According to various embodiments, the additional layer is formed under the substrate, between the substrate and the first electrode layer, between the first electrode layer and the first organic functional layer structure, between the first organic functional layer structure and the second electrode layer, between the second electrode layer and the second organic functional layer structure, between the second organic functional layer structure and the third electrode layer, between the third electrode layer and the cover layer, and/or over the cover layer. Furthermore, the additional layer may be formed over, under or in the encapsulation layer. The additional layer may be formed from one, two or more sublayers. The additional layer, or optionally its sublayers, may be formed as an output layer, an output structure, a planarization layer and/or as a matrix including refractive or diffractive elements. The output structure may be formed as a processed sublayer of the substrate, of the electrode layers, of the organic functional layer structures or of the cover layer. For example, the additional layer may be formed by means of local heating of the material of the substrate, of the corresponding electrode layer, of the corresponding organic functional layer structure, or of the cover layer. The local heating of the material of the respective layer may be carried out for example by using a laser, preferably in such a way that internal laser etching of the respective layer is carried out.

In various embodiments, a device for separating a room includes the optoelectronic component. The device may, for example, be a window or a door, for example a partition window between two rooms, for example a window of a conference room, or a door of a piece of furniture, for example a cupboard door.

In various embodiments, a piece of furniture includes the device. The piece of furniture is, for example, a display cabinet or a cupboard.

The use of the device and of the optoelectronic component in display cabinets, cupboards and in conference rooms, in which the use of frosted glass is desired, can contribute to ensuring a private area or concealing the content even when switched off. These surfaces may be combined with the very efficient lighting in two emission directions.

It should be pointed out that the one or more local modifying structures may be formed in such a way that they are scarcely perceptible to the human eye but nevertheless scatter a part of the light so as to improve the output of the light.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1 shows an optoelectronic component according to various embodiments;

FIG. 2 shows an optoelectronic component according to various embodiments;

FIG. 3 shows an optoelectronic component according to various embodiments;

FIG. 4 shows an optoelectronic component according to various embodiments;

FIG. 5 shows a flow chart in which a method for producing an optoelectronic component according to various embodiments is represented;

FIG. 6 shows a window including an optoelectronic component; and

FIG. 7 shows a piece of furniture including an optoelectronic component.

### DETAILED DESCRIPTION

The following detailed description refers to the accompanying drawing that show, by way of illustration, specific details and embodiments in which the disclosure may be practiced.

In the following detailed description, reference is made to the appended drawings, which form part thereof and in which specific embodiments in which the disclosure may be implemented are shown for illustration. In this regard, direction terminology such as “up”, “down”, “forward”, “backward”, “front”, “rear”, “on”, “over”, “under” etc. is used with reference to the orientation of the figure or figures being described. In the scope of this description, terms such as “connected” and “coupled” are used to describe both direct and indirect connection, and direct or indirect coupling. Since components of embodiments can be positioned in a number of different orientations, the direction terminology is used for illustration and is in no way restrictive. It is to be understood that other embodiments may be used and structural or logical modifications may be carried out, without departing from the protective scope of the present disclosure. It is to be understood that the features of the various embodiments described herein may be combined with one another, unless specifically indicated otherwise. The following detailed description is therefore not to be interpreted in a restrictive sense, and the protective scope of the present disclosure is defined by the appended claims. In the figures, elements which are identical or similar are provided with identical references, insofar as this is expedient.

In various embodiments, the optoelectronic component may be formed as an organic light-emitting diode (OLED), as an organic photodiode (OPD), as an organic solar cell (OSC) or as an organic transistor, for example as an organic thin-film transistor (OTFT). In various embodiments, the optoelectronic component may be part of an integrated circuit. Furthermore, a multiplicity of optoelectronic components may be provided, for example fitted in a common housing.

The term “translucent layer” may in various embodiments be interpreted as meaning that a layer is transmissive for light, for example for the light generated by the optoelectronic component, for example of one or more wavelength ranges, for example for light in a wavelength range of visible light (for example at least in a subrange of the wavelength range from 380 nm to 780 nm). For example, the term “translucent layer” is to be interpreted in various embodiments as meaning that essentially all the whole amount of light input into a structure (for example a layer) is also output from the structure (for example layer).

The term “transparent layer” may in various embodiments be interpreted as meaning that a layer is transmissive for light (for example at least in a subrange of the wavelength range from 380 nm to 780 nm), light input into a structure (for example a layer) also being output from the structure (for example layer) essentially without scattering or light conversion.

In contrast thereto, the term “nontransparent layer” may in various embodiments be interpreted as meaning that a layer is not transmissive for light, for example in a subrange of the wavelength range from 380 nm to 780 nm and/or in the wavelength range in which the light from an organic functional layer structure of the optoelectronic component lies.

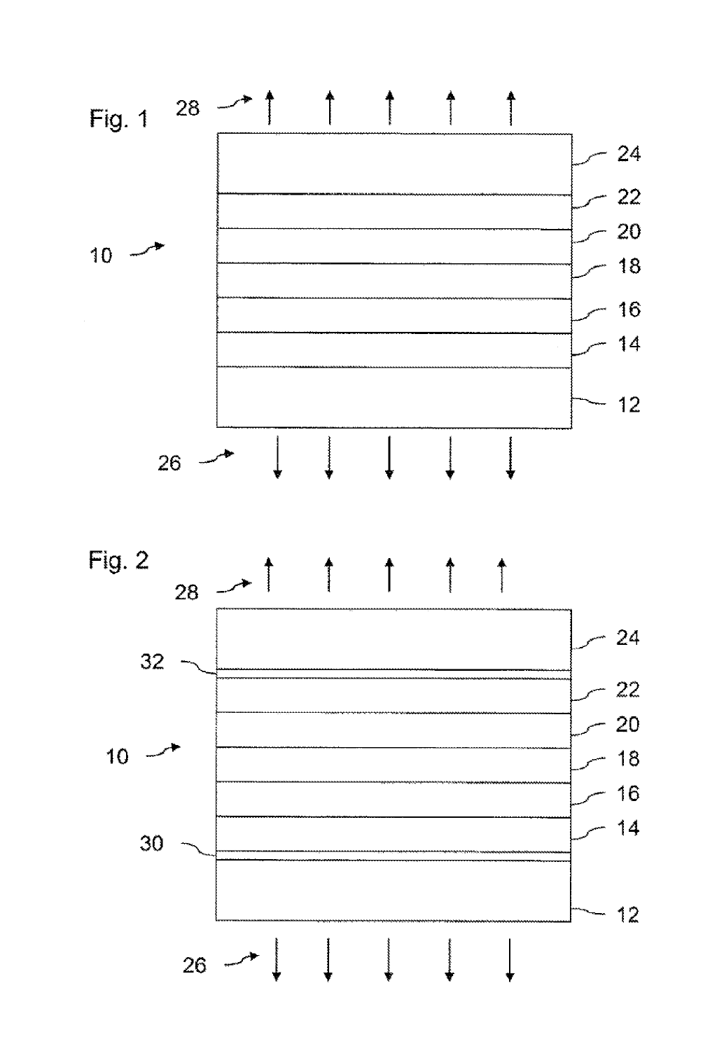

FIG. 1 shows an embodiment of an optoelectronic component 10. The optoelectronic component 10 includes a substrate 12 and a first electrode layer 14 on the substrate 12. A first organic functional layer structure 16 is formed on or over the first electrode layer 14. A nontransparent second electrode layer 18 is formed on or over the first organic functional layer structure 16, and a second organic functional layer structure 20 is formed on or over the second electrode layer 18. A third electrode layer 22 is formed on or over the second organic functional layer structure 20. A cover layer 24 is formed on the third electrode layer 22.

The optoelectronic component 10 allows efficient light emission in two opposite emission directions, for example in a first emission direction 26 and in a second emission direction 28. For example, the first electrode layer 14, the first organic functional layer structure 16 and the second electrode layer 18 may be formed as a bottom emitter, and/or the second electrode layer 18, the second organic functional layer structure 20 and the third electrode layer 22 may be formed as a top emitter.

The substrate 12 may include a glass and/or one or more sheets, and/or may be provided with one or more barrier layers. The cover layer 24 may include a glass, one or more sheets, or a coating.

For example, the substrate 12 may include or be formed from glass, quartz and/or a semiconductor material, or any other suitable material. Furthermore, the substrate 12 may include or be formed from a plastic sheet or a laminate including one or more plastic sheets. The plastic may include or be formed from one or more polyolefins (for example high or low density polyethylene (PE), or polypropylene (PP)). Furthermore, the plastic may include or be formed from polyvinyl chloride (PVC), polystyrene (PS), polyester and/or polycarbonate (PC), polyethylene terephthalate (PET), polyether sulfone (PES) and/or polyethylene naphthalate (PEN). The substrate 12 may include one or more of the materials mentioned above. The substrate 12 may be configured so as to be transparent, translucent, partially translucent, partially transparent, or opaque.

The cover layer 24 may for example include or be formed from glass or another suitable material, for example one of the following materials: quartz, a semiconductor material, a plastic sheet or a laminate including one or more plastic sheets. The plastic may include or be formed from one or more polyolefins (for example high or low density polyethylene (PE), or polypropylene (PP)). Furthermore, the plastic may include or be formed from polyvinyl chloride (PVC), polystyrene (PS), polyester and/or polycarbonate (PC), polyethylene terephthalate (PET), polyether sulfone (PES) and/or polyethylene naphthalate (PEN). The cover layer 24 may be configured so as to be translucent, for example transparent, partially translucent, for example partially transparent. The cover layer 24 may have a layer thickness in a range of from approximately 1 μm to approximately 50 μm, for example in a range of from approximately 5 μm to approximately 40 μm, for example in a range of from approximately 10 μm to approximately 25 μm.

The two organic functional layer structures 16, 20 may have different emission characteristics; for example, one of the layer structures may have a warm, for example warm-white, emission characteristic and the other of the layer structures may have a cold, for example cold-white, emission characteristic. The emission may furthermore be directed, for example along a surface normal on the substrate 12 or on the cover layer 24. Furthermore, a Lambertian emission profile, a butterfly-shaped emission profile, etc. may be produced for each of the emission directions 26, 28, independently of the respective other emission direction. Furthermore, one of the organic functional layer structures 16, 20 may emit light of a different color than the other organic functional layer structure 16, 20. The organic functional layer structures 16, 20 include at least one transport layer each and one emitter layer each. The organic functional layer structures 16, 20 may each contain one or more emitter layers, for example including fluorescent and/or phosphorescent emitters, as well as one or more hole conduction layers each.

Examples of emitter materials which may be used in the optoelectronic component 10 according to various embodiments for the emitter layer or layers include organic or organometallic compounds, such as derivatives of polyfluorene, polythiophene and polyphenylene (for example 2- or 2,5-substituted poly-p-phenylene vinylene) and metal complexes, for example iridium complexes, for example blue phosphorescent FIrPic (bis(3,5-difluoro-2-(2-pyridyl)phenyl-(2-carboxypyridyl) iridium III), green phosphorescent Ir(ppy)3 (tris(2-phenylpyridine) iridium III), red phosphorescent Ru (dtb-bpy)3*2(PF6) (tris[4,4′-di-tert-butyl-(2,2′)-bipyridine]ruthenium(III) complex) and blue fluorescent DPAVBi (4,4-bis[4-(di-p-tolylamino)styryl]biphenyl), green fluorescent TTPA (9,10-bis[N,N-di-(p-tolyl)amino]anthracene) and red fluorescent DCM2 (4-dicyanomethylene)-2-methyl-6-julolidyl-9-enyl-4H-pyrane) as nonpolymeric emitters. Such nonpolymeric emitters may, for example, be deposited by means of thermal evaporation. Furthermore, polymeric emitters may be used, which may in particular be deposited by means of wet chemical methods, for example spin coating. The emitter materials may be embedded in a suitable way in a matrix material.

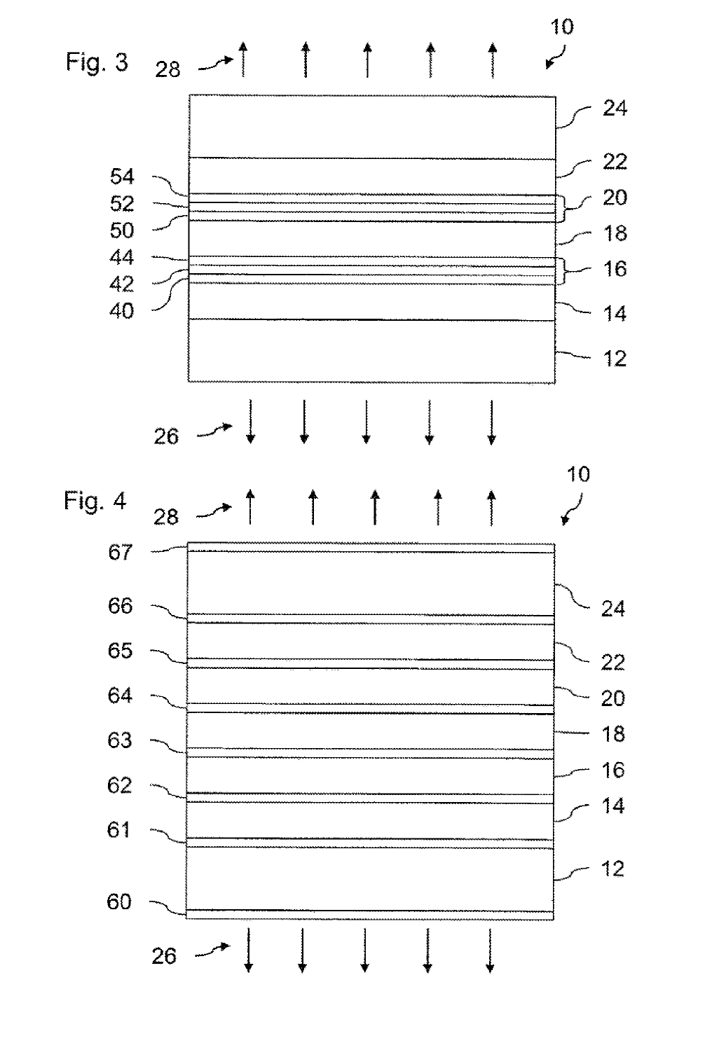

The emitter materials of the emitter layer or layers of the optoelectronic component 10 may, for example, be selected in such a way that the optoelectronic component 10 emits white light in at least one of the two emission directions 26, 28. The emitter layer or layers may include a plurality of emitter materials emitting different colors (for example blue and yellow or blue, green and red), or alternatively the emitter layer or layers may also, as explained in more detail below with reference to FIG. 3, be constructed from a plurality of functional sublayers, such as a blue fluorescent emitter layer or blue phosphorescent emitter layer, a green phosphorescent layer and a red phosphorescent emitter layer. Mixing the different colors can lead to the emission of light with a white color impression. As an alternative, a converter material may also be arranged in the beam path of the primary emission generated by these layers, which material at least partially absorbs the primary radiation and emits secondary radiation of a different wavelength, so that a white color impression is obtained from (not yet white) primary radiation by the combination of primary and secondary radiation.

The organic functional layer structures 16, 20 may generally each include one or more functional sublayers. The one or more functional sublayers may include organic polymers, organic oligomers, organic monomers, nonpolymeric organic small molecules, or a combination of these materials. For example, the organic functional layer structure or structures 16, 20 may include one or more functional sublayers which is or are configured as a hole transport layer, so that, for example in the case of an OLED, effective hole injection into an electroluminescent layer or an electroluminescent region is made possible. For example, tertiary amines, carbazo derivatives, conductive polyaniline or polyethylene dioxythiophene may be used as a material for the hole transport layer. In various embodiments, the one or more functional sublayers may be configured as an electroluminescent layer. In various embodiments, the hole transport layer of the first organic functional layer structure 16 may be applied, for example deposited, on or over the first electrode layer 14, and the emitter layer of the first organic functional layer structure 16 may be applied, for example deposited, on or over the hole transport layer of the first organic functional layer structure 16. Furthermore, the hole transport layer of the second organic functional layer structure 20 may be applied, for example deposited, on or over the second electrode layer 18, and the emitter layer of the second organic functional layer structure 20 may be applied, for example deposited, on or over the hole transport layer of the second organic functional layer structure 20.

The optoelectronic component 10 may generally include further organic functional layers, which are used to further improve the functionality and therefore the efficiency of the optoelectronic component 10.

In various embodiments, the first organic functional layer structure 16 and/or the second organic functional layer structure 20 may have a layer thickness of up to 1.5 μm, for example a layer thickness of up to 1.2 μm, for example a layer thickness of up to 1 μm, for example a layer thickness of up to 800 nm, for example a layer thickness of up to 500 nm, for example a layer thickness of up to 400 nm, for example a layer thickness of up to 300 nm.

The first and third electrode layers 14, 18 are preferably formed so as to be transparent or translucent, the first electrode layer 14 being translucent or transparent at least for the light from the first organic functional layer structure 16, and the third electrode layer 22 being translucent or transparent at least for the light from the second organic functional layer structure 20. Conversely, the second electrode layer 18 is formed so as to be nontransparent or nontranslucent for the light from the first and/or second organic functional layer structure 16, 20. As an alternative or in addition, the second electrode layer 18 may be nontransparent or nontranslucent for light in the visible wavelength range. The second electrode layer 18 may, for example, be formed so as to be reflective. For example, by selecting particular materials for the second electrode layer 18, an impression which is matt on both sides, matt on one side and/or reflective on one side, or reflective on both sides, may be imparted. Furthermore, a viewing angle dependency on the two sides may be set to be the same or different.

The electrode layers 14, 18, 20 are electrically coupled to a control circuit (not represented), with the aid of which a voltage can be applied between the first and second electrode layers 14, 18 and/or between the second and third electrode layers 18, 22. In this way, the first organic functional layer structure 16 or the second organic functional layer structure 20 can be stimulated to emit light. This leads to selective emission of light in the first emission direction 26 and/or the second emission direction 28.

The first and/or third electrode layer 14, 22 may be formed from an electrically conductive material or be such a material, for example a metal or a transparent conductive oxide (TCO) or a layer stack of a plurality of layers of the same metal or different metals and/or of the same TCO or different TCOs. Transparent conductive oxides are transparent conductive materials, for example metal oxides, for example zinc oxide, tin oxide, cadmium oxide, titanium oxide, indium oxide or indium tin oxide (ITO). Besides binary metal-oxygen compounds, for example ZnO, SnO₂, or In₂O₃, ternary metal-oxygen compounds, for example Zn₂SnO₄, CdSnO₃, ZnSnO₃, MgIn₂O₄, GaInO₃, Zn₂In₂O₅ or In₄Sn₃O₁₂, or mixtures of different transparent conductive oxides also belong to the TCO group. Furthermore, the TCOs do not necessarily correspond to a stoichiometric composition, and may furthermore be p-doped or n-doped. The first and/or third electrode layers 14, 22 may be formed as an anode, i.e. as a hole-injecting material.

In various embodiments, the first and/or third electrode layer 14, 22 may be formed by a layer stack of a combination of a layer of a metal on a layer of a TCO, or vice versa. One example is a silver layer which is applied on an indium tin oxide (ITO) layer (Ag on ITO). In various embodiments, the first and/or third electrode layer 14, 22 may include a metal (for example Ag, Pt, Au, Mg) or a metal alloy of the described materials (for example an AgMg alloy). In various embodiments, the first and/or third electrode layer 14, 22 may include AlZnO or similar materials.

In various embodiments, the first and/or third electrode layer 14, 22 may include a metal which, for example, may be used as a cathode material, i.e. as an electron-injecting material. Inter alia, for example, Al, Ba, In, Ag, Au, Mg, Ca or Li, and compounds, combinations or alloys of these materials, may be present as cathode material in various embodiments.

The first and/or third electrode layer 14, 22 may have a layer thickness of less than or equal to 25 nm, for example a layer thickness of less than or equal to 20 nm, for example a layer thickness of less than or equal to 18 nm. Furthermore, the first and/or third electrode layer 14, 22 may for example have a layer thickness greater than or equal to 10 nm, for example a layer thickness greater than or equal to 5 nm. In various embodiments, the first and/or third electrode layer 14, 22 may have a layer thickness in a range of from approximately 10 nm to approximately 25 nm, for example a layer thickness in a range of from approximately 10 nm to approximately 18 nm, for example a layer thickness in a range of from approximately 15 nm to approximately 18 nm.

In various embodiments, the second electrode layer 18 may for example have a layer thickness of less than or equal to 50 nm, for example a layer thickness of less than or equal to 45 nm, for example a layer thickness of less than or equal to 40 nm, for example a layer thickness of less than or equal to 35 nm, for example a layer thickness of less than or equal to 30 nm, for example a layer thickness of less than or equal to 25 nm, for example a layer thickness of less than or equal to 20 nm, for example a layer thickness of less than or equal to 15 nm, for example a layer thickness of less than or equal to 10 nm. In various embodiments, the second electrode layer 18 may have an arbitrarily larger layer thickness.

FIG. 2 shows an embodiment of an optoelectronic component 10, which may be formed essentially in the same way as the optoelectronic component 10 of the embodiment shown in FIG. 1, although, in contrast to the embodiment shown in FIG. 1, in addition a first encapsulation layer 30 is arranged between the substrate 12 and the first electrode layer 14 and a second encapsulation layer 32 is arranged between the third electrode layer 22 and the cover layer 24. The encapsulation layers 30, 32 are used to protect the electrode layers 14, 18, 22 and the organic functional layer structures 16, 20, for example against moisture, oxygen, corrosion or dirt. The encapsulation layers 30, 32 are preferably formed so as to be transparent or translucent, for example in the wavelength ranges of the light which the organic functional layer structures 16, 20 emit.

In various embodiments, the expression “encapsulated” or “encapsulation” is intended for example to mean that a barrier is provided against moisture and/or oxygen, so that the correspondingly encapsulated organic functional layer structure 16, 20 cannot be penetrated by these substances. In various embodiments, the encapsulation layers 30, 32 may include or consist of one or more of the following materials: a material or a mixture of materials or a stack of layers of materials, for example SiO2; Si3N4; SiON (these materials are deposited, for example, by means of a CVD method); Al2O3; ZrO2; TiO2; Ta2O5; SiO2; ZnO; and/or HfO2 (these materials are deposited, for example, by means of an ALD method); or a combination of these materials.

FIG. 3 shows an embodiment of an optoelectronic component 10, which may be formed essentially in the same way as the optoelectronic component 10 of the embodiment shown in FIG. 1, although, in contrast to the embodiment shown in FIG. 1, the first organic functional layer structure 16 includes a first functional sublayer 40, a second functional sublayer 42 and a third functional sublayer 44, and the second organic functional layer structure 20 includes a fourth functional sublayer 50, a fifth functional sublayer 52 and a sixth functional sublayer 54. The functional sublayers 40 to 54 for may emit light of different colors. For example, the first and fourth functional sublayers 40, 50 may emit light of a first color, for example red light, the second and fifth functional sublayers 42, 52 may emit light of a second color, for example green light, and the third and sixth functional sublayers 42, 52 may emit light of a third color, for example blue light. In this context, the first and second organic functional layer structures 16, 20 may include further intermediate electrode layers, which are arranged for example between the first and second functional sublayers 40, 42, the second and third functional sublayers 42, 44, the fourth and fifth functional sublayers 50, 52 and/or the fifth and sixth functional sublayers 52, 54, for selective driving of the individual functional sublayers 40 to 54. Furthermore, individual sublayers or each of the sublayers 40 to 54 may respectively include one transport layer each and one emitter layer each.

Depending on the way they are driven, the functional sublayers 40 to 54 make it possible to emit light of different colors, in which case light of a different color may be emitted in the first emission direction 26 than in the second emission direction 28. Furthermore, within one of the organic functional layer structures 16, 20, the light from one or two of the functional sublayers 40 to 54 may be mixed with the light from two or one of the other functional sublayers, for example in order to generate white light, so that the corresponding organic functional layer structure 16, 20 emits light that is composed of the light of the individual functional sublayers 40 to 54.

FIG. 4 shows an embodiment of an optoelectronic component 10, which may be formed essentially in the same way as the optoelectronic component 10 of the embodiment shown in FIG. 1, although, in contrast to the embodiment shown in FIG. 1, a first additional layer 60 is formed under the substrate 12, in addition or as an alternative a second additional layer 61 is formed between the substrate 12 and the first electrode layer 14, in addition or as an alternative a third additional layer 62 is formed between the first electrode layer 14 and the first organic functional layer structure 16, in addition or as an alternative a fourth additional layer 63 is formed between the first organic functional layer structure 16 and the second electrode layer 18, in addition or as an alternative a fifth additional layer 64 is formed between the second electrode layer 18 and the second organic functional layer structure 20, in addition or as an alternative a sixth additional layer 65 is formed between the second organic functional layer structure 20 and the third electrode layer 22, in addition or as an alternative a seventh additional layer 66 is arranged between the third electrode layer 22 and the cover layer 24, and/or in addition or as an alternative an eighth additional layer 67 is formed over the cover layer 24. Optionally, further additional layers may be formed over and/or under the encapsulation layers 30, 32 (see FIG. 2).

The first additional layer 60 under the substrate 12 or the eighth additional layer 67 on the cover layer 24 may be formed as external output structures. The other additional layers 61 to 66 may be formed as internal output structures. With the aid of the additional layers 60 to 67, the transmissivity or the reflectivity of the electrode layers 14, 18, 20 or the emission ratio in the two emission directions 26, 28 may, for example, be set. Furthermore, an output efficiency of the light generated may be improved. Furthermore, with the aid of the additional layers 60, 61, 62 under the first electrode layer 14 and/or with the aid of the additional layers 65, 66, 67 over the third electrode layer 22, an emission of light of a different color may be set in the two emission directions 26, 28, for example by the corresponding additional layers 60, 61, 62, 65, 66, 67 being formed as color filters. Furthermore, the color temperature of the light emitted may be set with the aid of the additional layers 60 to 67, for example by using electrochromic or thermochromic additional layers 60 to 67. For example, a color temperature of between 2500 K and 4000 K may be set in the first emission direction 30, for example as direct lighting, and a color temperature of from 4000 K to 6500 K may be set in the second emission direction 32, for example as indirect lighting. Furthermore, it may be set that 45% of the amount of light generated is emitted in the first emission direction 30, and that 55% of the amount of light generated is emitted in the second emission direction 32.

Each of the additional layers or individual additional layers 60 to 67 may each include one, two or more sublayers. Furthermore, each of the additional layers or individual additional layers 60 to 67, or optionally their sublayers, may include output layers, output structures, planarization layers and/or refractive or diffractive elements in a matrix. The output structures may be processed sublayers of the substrate 12, of the electrode layers 14, 18, 22, of the organic functional layer structures 16, 20, of the encapsulation layers 30, 32, or of the cover layer 24. For example, the output structure may be texturing of the substrate 12, of the electrode layers 14, 18, 22, of the organic functional layer structures 16, 20, of the encapsulation layers 30, 32, or of the cover layer 24.

For example, one or more of the additional layers 60 to 67 may be formed as modifying structures. For example, the first and/or the second additional layer 60, 61 may be provided for output of the substrate modes within the substrate (for example a glass substrate) 12 at at least one predetermined position (or at a plurality of predetermined positions) (respectively) as a local modifying structure of the material of the substrate 12. Furthermore, the seventh and/or eighth additional layer 66, 67 may be provided for output of the substrate modes within the cover layer (for example a glass cover layer) 24 at at least one predetermined position (or at a plurality of predetermined positions) (respectively) as a local modifying structure of the material of the cover layer 24. In various embodiments, the local modifying structure or structures is or are formed in the form of etching, for example in the form of substrate or cover layer internal etching. In various embodiments, the local modifying structure or structures is or are formed in the form of a nonperiodic structure. This local modifying structure, or these local modifying structures, scatter the light generated, for example, by the emitter layers, which is guided into the substrate 12, or the cover layer 24. An advantage of this configuration is that the surface of the substrate 12, or of the cover layer 24, (for example the glass surface) retains its reflective impression as before. In this way, the off-state appearance of the optoelectronic component 10 can additionally be improved. The one or more local modifying structures may be formed at predetermined or predefined positions within the substrate 12 or the cover layer 24, so that desired artificially produced scattering structures (not irregularities in the material of the respective layer attributable to nondeterministic and undesired irregularities) are formed. The one or more local modifying structures may all have the same size or different sizes. The arrangement of a plurality of local modifying structures in one or more layers may be random, in other words nonperiodic. As an alternative, the local modifying structures may be arranged in a predetermined (for example periodic) pattern. Furthermore, by means of the plurality of local modifying structures, a local deterministic structure, for example a lens structure, may be formed in one or more layers.

The one or more local modifying structures in the cover layer 24 form scattering centers there. In this way, the output of light in the second emission direction 28 can be improved, for example by the cover layer 302 (forexample the cover glass) including one or more local modifying structures (for example in the form of internal etching).

For output of modes guided in the organic functional layer structures 16, 20 of the optoelectronic component 10, under certain circumstances it may not be sufficient to provide, for example internally etch, the substrate 12 and/or the cover layer 24 with one or more local modifying structures, since, owing to the refractive index discontinuity usually existing between the organic functional layer structures 16, 20, the electrode layers 14, 18, 22, the cover layer 24 and the substrate 202 because of the materials used, the light at least partially does not reach into the cover layer 24 or the substrate 12 (for example the glass substrate). This aspect may be countered in various ways by the local modifying structures.

For example, one of the additional layers 60 to 67 may be formed as a transparent high-index layer (for example of silicon nitride and/or titanium oxide), or as a stack of a plurality of transparent high-index layers. The one or more local modifying structures may be provided in the transparent high-index layer or in the stack of a plurality of transparent high-index layers. For example, the transparent high-index layer or the stack of a plurality of transparent high-index layers may be internally etched. The light coming from the layers of the organic functional layer structures 16, 20 can be scattered in the corresponding transparent high-index layer or in the stack of a plurality of transparent high-index layers, so that it can be output. In this case, for example, the one or more local modifying structures may also be provided at the interfaces of the individual layers.

If the local modifying structures have a size in the sub-μm range, in various embodiments it is possible for the local modifying structures to be arranged in a nonperiodic pattern. If the local modifying structures have a size of at least 1 μm, in various embodiments it is possible for the local modifying structures to be arranged in a periodic pattern. It should, however, be pointed out that the local modifying structures may be arranged nonperiodically even in the case in which the local modifying structures have a size of at least 1 μm.

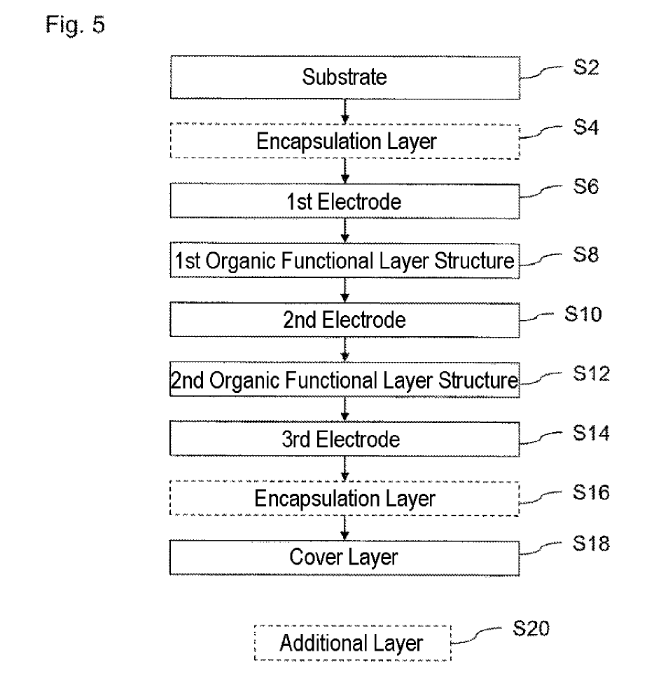

FIG. 5 shows a flow chart of a method for producing the optoelectronic component 10.

In a step S2, the substrate 12 is provided. The substrate 12 is formed, for example, from a glass or a sheet, and may be provided with the first additional layer 60, which may be formed as a barrier layer.

In a step S4, which may be carried out optionally, the first encapsulation layer 30 is formed on the substrate 12. The first encapsulation layer 30 is preferably formed so as to be transparent.

In a step S6, a first electrode layer 14 is formed on the substrate 12, or optionally on the first encapsulation layer 30. The first electrode layer 14 is, for example, formed so as to be transparent and electrically coupled to the control circuit.

In a step S8, the first organic functional layer structure 16 is formed on or over the first electrode layer 14, for example by forming one or more transport layers and one or more emitter layers, and/or by forming the functional sublayers 40, 42, 44.

In a step S10, a second electrode layer 18 is formed on or over the first organic functional layer structure 16. The second electrode layer 18 is formed so as to be nontransparent. For example, the second electrode layer 18 is formed so as to be matt on one side and reflective on the other side, or matt on both sides, or reflective on both sides. Furthermore, the second electrode layer 18 is electrically coupled to the control circuit.

In a step S12, the second organic functional layer structure 20 is formed on or over the second electrode layer 18, for example in a way corresponding to the first organic functional layer structure 16.

In a step S14, the third electrode layer 22 is formed on or over the second organic functional layer structure 20, for example in a way corresponding to the first electrode layer 14.

In a step S16, which may be carried out optionally, the second encapsulation layer 32 is formed over the third electrode layer 22, for example in a way corresponding to the first encapsulation layer 30.

In a step S18, the cover layer 24 is formed on or over the third electrode layer 22, or optionally on the second encapsulation layer 32, for example from glass, a sheet or a coating. The glass or the sheet may be adhesively bonded on the third electrode layer 22 or on the second encapsulation layer 32.

In an additional step S20, which may be carried out between one, two or more of the steps S2 to S18 above, the additional layer or layers 60 to 67 and/or their sublayers are formed. The additional layers 60 to 67 may, for example, be applied as additional material layers, or the additional layers 60 to 67 may be formed by means of local heating of the material of the substrate 12, of the corresponding electrode layer 14, 18, 22, of the corresponding organic functional layer structure 16, 20, of the cover layer 24 or of the encapsulation layers 30, 32. The local heating of the material of the respective layer is carried out, for example, by using a laser, preferably in such a way that internal laser etching of the respective layer is carried out.

In various embodiments, a combination of a plurality of etched layers may also be provided in the optoelectronic component 10. It is also possible to etch one or more layers only to a small extent.

For example, the technique of internal etching (by using one or more lasers) makes it possible to scribe or form any desired structures within the layers. In various embodiments, these may for example be in particular scattering layers; as an alternative or in addition, three-dimensional structures, which may for example cause lens effects, may also be scribed or formed within one or more layers of the optoelectronic component 10. In this way, it is also possible to create special effects for the end use, for example bright luminous script in the light pattern of the organic light-emitting diode.

Since, for example, per se all optionally translucent, for example transparent, materials may be provided for the internal laser etching, the substrate 12 or the cover layer 24 need not necessarily consist of glass. It is likewise possible, for example, for it to consist of or include plastic or other translucent, for example transparent, materials.

In various embodiments, therefore, the substrate modes and/or the modes of the other layers, for example the modes of the electrode layers 14, 18, 22 (for example ITO modes) and/or the modes of the organics, i.e. of the organic functional layer structures 16, 20, are output; these modes are also referred to as an ITO/organics mode.

In various embodiments, the etching may be formed as far as a few nm from the interfaces of a layer (although the interface should not be destroyed, except for the embodiments in which the interface is to be intentionally structured).

The optoelectronic component 10 may, for example, be used in a device for separating a room.

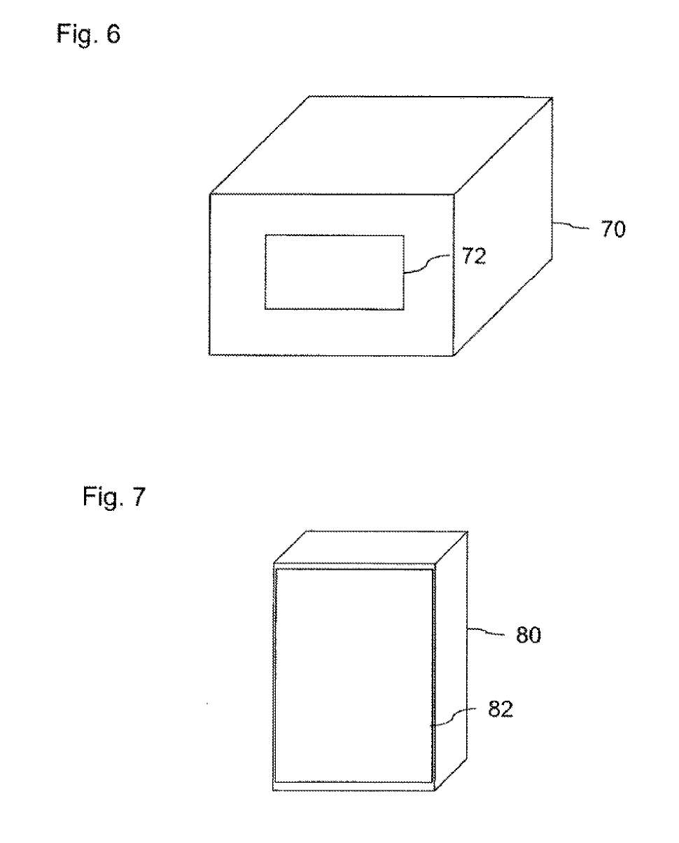

FIG. 6 shows, as a device for separating a room 70, by way of example a window 72 which is formed essentially from one or more optoelectronic components 10. The window 72 is, for example, an exterior window or a partition window between two rooms, for example a window to a conference room. As an alternative or in addition to the window, the corresponding room 70 may also be separated by a door which includes the optoelectronic component 10.

FIG. 7 shows, as a device for separating a room, for example a piece of furniture 80, the door 82 of which is essentially formed by one or more optoelectronic components 10, the room being for example the interior of the piece of furniture 80. The piece of furniture 80 is, for example, a display cabinet or a cupboard.

The invention is not limited to the embodiments indicated. For example, the embodiments may be combined with one another. For example, the additional layers 60 to 67 and the encapsulation layers 30, 32 may be provided. Furthermore, the additional layers 60 to 67 and the functional sublayers 40, 42, 22, 50, 52, 54 may be provided. Furthermore, the encapsulation layers 30, 32 and the functional sublayers 40, 42, 22, 50, 52, 54 may be provided. Furthermore, fewer additional layers 60 to 67, fewer functional sublayers 40, 42, 22, 50, 52, 54, or only one of the encapsulation layers 30, 32 may be provided. Furthermore, further additional layers 60 to 67, further functional sublayers 40, 42, 22, 50, 52, 54, or further encapsulation layers 30, 32 may be provided.

### LIST OF REFERENCES

10 optoelectronic component
12 substrate
14 first electrode layer
16 first organic functional layer structure
18 second electrode layer
20 second organic functional layer structure
22 third electrode layer
24 cover layer
26 first emission direction
28 second emission direction
30 first encapsulation layer
32 second encapsulation layer
40 first functional sublayer
42 second functional sublayer
44 third functional sublayer
50 fourth functional sublayer
52 fifth functional sublayer
54 sixth functional sublayer
60 first additional layer
61 second additional layer
62 third additional layer
63 fourth additional layer
64 fifth additional layer
65 sixth additional layer
66 seventh additional layer
67 eighth additional layer
70 room
72 window
80 piece of furniture
82 door
S2-S20 steps two to twenty

1. An optoelectronic component, comprising:
a first electrode layer;
a first organic functional layer structure on or over the first electrode layer;
a nontransparent second electrode layer on or over the first organic functional layer structure;
a second organic functional layer structure on or over the second electrode layer; and
a third electrode layer on or over the second organic functional layer structure,
wherein the material for the second electrode layer is selected in such a way that a matt impression of at least one side of the optoelectronic component is imparted.

2. The optoelectronic component as claimed in claim 1, further comprising a substrate, wherein the first electrode layer is arranged on or over the substrate.

3. The optoelectronic component as claimed in claim 1, further comprising a cover layer on or over the third electrode layer.

4. The optoelectronic component as claimed in claim 1, further comprising at least one encapsulation layer, over which the first electrode layer is arranged, and/or which is arranged over the third electrode layer.

5. The optoelectronic component as claimed in claim 1, further comprising at least one additional layer,
over which the substrate is arranged,
which is arranged between the substrate and the first electrode layer,
which is arranged between the first electrode layer and the first organic functional layer structure,
which is arranged between the first organic functional layer structure and the second electrode layer,
which is arranged between the second electrode layer and the second organic functional layer structure,
which is arranged between the second organic functional layer structure and the third electrode layer,
which is arranged between the third electrode layer and the cover layer, and/or
which is arranged over the cover layer.

6. The optoelectronic component as claimed in claim 5, wherein the additional layer comprises one, two or more sublayers.

7. The optoelectronic component as claimed in claim 5, wherein the additional layer comprises an output layer, an output structure, a planarization layer, and/or refractive or diffractive elements in a matrix.

8. A method for producing an optoelectronic component, the method comprising:
forming a first electrode layer;
forming a first organic functional layer structure on or over the first electrode layer;
forming a nontransparent second electrode layer on or over the first organic functional layer structure;
forming a second organic functional layer structure on or over the second electrode layer; and
forming a third electrode layer on or over the second organic functional layer structure,
wherein the material for the second electrode layer is selected in such a way that a matt impression of at least one side of the optoelectronic component is imparted.

9. The method as claimed in claim 8, wherein a substrate is provided, and the first electrode layer is formed on or over the substrate.

10. The method as claimed in claim 8, wherein a cover layer is formed on or over the third electrode layer.

11. The method as claimed in claim 8, wherein at least one encapsulation layer is formed under the first electrode layer and/or over the third electrode layer.

12. The method as claimed in claim 8, wherein an additional layer is formed
under a substrate,
between the substrate and the first electrode layer,
between the first electrode layer and the first organic functional layer structure,
between the first organic functional layer structure and the second electrode layer,
between the second electrode layer and the second organic functional layer structure,
between the second organic functional layer structure and a third electrode layer,
between the third electrode layer and a cover layer, and/or
over the cover layer.

13. The method as claimed in claim 12, wherein the additional layer comprises one, two or more sublayers.

14. The method as claimed in claim 12, wherein the additional layer is formed as an output layer, an output structure, a planarization layer and/or as a matrix comprising refractive or diffractive elements.

15. The method as claimed in claim 12, wherein the additional layer is formed by means of local heating of the material of the substrate, of the corresponding electrode layer, of the corresponding organic functional layer structure, or of the cover layer.

16. The method as claimed in claim 15, wherein the local heating of the material of the respective layer is carried out by using a laser.

17. A device for separating a room, which comprises an optoelectronic component,
the optoelectronic component comprising:
a first electrode layer;
a first organic functional layer structure on or over the first electrode layer;
a nontransparent second electrode layer on or over the first organic functional layer structure;
a second organic functional layer structure on or over the second electrode layer; and
a third electrode layer on or over the second organic functional layer structure,
wherein the material for the second electrode layer is selected in such a way that a matt impression of at least one side of the optoelectronic component is imparted.

18. (canceled)
